(19) United States
(12) Patent Application Publication
(10) Pub. No.: US 2026/0009855 A1
(43) Pub. Date: Jan. 8, 2026

(54) METHOD AND APPARATUS FOR MONITORING A BATTERY STATE ESTIMATOR

(71) Applicant: GM GLOBAL TECHNOLOGY OPERATIONS LLC, Detroit, MI (US)

(72) Inventors: Shobhit Gupta, Sterling Heights, MI (US); Insu Chang, Troy, MI (US); Bharatkumar Hegde, Bloomfield Hills, MI (US); Ibrahim Haskara, Macomb, MI (US); Su-Yang Shieh, Clawson, MI (US)

(73) Assignee: GM GLOBAL TECHNOLOGY OPERATIONS LLC, Detroit, MI (US)

(21) Appl. No.: 18/761,733

(22) Filed: Jul. 2, 2024

(51) Int. Cl. G01R 31/367; B60R 16/033; G01R 31/371; G01R 31/3835; G01R 31/396; H02J 7/00

(52) U.S. Cl. CPC G01R 31/367; G01R 31/371; G01R 31/3835; G01R 31/396; H02J 7/0048; H02J 7/007182; B60R 16/033; H02J 7/00032

(57) ABSTRACT

A method and associated system for managing a battery cell includes determining, for a battery cell, a plurality of battery cell parameters; developing a plurality of on-vehicle reduced order linear data-driven battery models based upon the battery cell parameters, wherein each of the plurality of on-vehicle reduced order linear data-driven battery models determines corresponding model parameters; selecting one of the corresponding model parameters for one of the plurality of on-vehicle reduced order linear data-driven battery models based upon a previous state of charge for the battery cell; executing a derivative-free observer to determine a present state of charge (SOC) of the battery cell based upon the corresponding model parameters; and controlling the battery cell based upon the SOC.

### INTRODUCTION

A battery is a single cell or multi-cell electrochemical device that stores and delivers electrical energy to power devices. Batteries are employed on numerous devices, including hybrid or electric vehicles, cell phones, etc. A battery may experience a decrease in charge capacity as a result of time and usage.

Battery state estimation, particularly the estimation of a State of Charge (SOC), is employed for effective management and operation. The SOC indicates a remaining charge in a battery as a percentage of its total capacity, which helps in predicting the driving range, managing service life, and minimizing risk in the battery.

One form of monitoring the charge capacity of a battery is to execute a Battery State Estimation (BSE) routine, which tracks battery parameters. One method to estimate a charge capacity includes using voltage measurements that are taken during a resting period, i.e., when the device is neither charging nor discharging the battery. Such voltage measurements must be available over a wide range of states of charge to achieve accurate results, and may be precluded for some devices due to usage patterns.

When a battery is employed on a vehicle, a vehicle owner or fleet manager needs some form feedback with regard to a state of health of an on-vehicle battery, including a need for an automated alert when vehicle performance is affected due to degradation of the state of health of the on-vehicle battery.

### SUMMARY

The concepts described herein operate to monitor a rechargeable electrochemical battery in-use, including detecting when a charge capacity estimate has achieved a level of uncertainty that may interfere with and negatively affect performance of the system in which the battery is employed. When the level of uncertainty of the charge capacity estimate is greater than a desired level of uncertainty, some form of remedial action or maintenance may be indicated.

The concepts described herein include a method, and associated system for managing a battery cell. The method includes determining, for a battery cell, a plurality of battery cell parameters; developing a plurality of on-vehicle reduced order linear data-driven battery models based upon the battery cell parameters, wherein each of the plurality of on-vehicle reduced order linear data-driven battery models determines corresponding model parameters; selecting one of the corresponding model parameters for one of the plurality of on-vehicle reduced order linear data-driven battery models based upon a previous state of charge for the battery cell; executing a derivative-free observer to determine a present state of charge (SOC) of the battery cell based upon the corresponding model parameters; and controlling the battery cell based upon the SOC.

Another aspect of the disclosure may include executing a Kalman filter to determine the present state of charge (SOC) of the battery cell based upon the corresponding second set of parameters.

Another aspect of the disclosure may include executing the derivative-free observer to determine a voltage of the battery cell based upon the corresponding second set of parameters; and controlling charging of the battery cell based upon the SOC and the voltage of the battery cell.

Another aspect of the disclosure may include communicating the plurality of battery cell parameters to a remote server; developing a plurality of remote reduced order linear data-driven battery models based upon the battery cell parameters, wherein each of the remote reduced order linear data-driven battery models determines a corresponding remote model parameter; and updating the plurality of on-vehicle reduced order linear data-driven battery models based upon the corresponding remote model parameter.

Another aspect of the disclosure may include partitioning the plurality of remote reduced order linear data-driven battery models based upon the state of charge of the battery cell; determining the corresponding remote model parameter for each of the plurality of remote reduced order linear data-driven battery models that are partitioned based upon the state of charge of the battery cell; partitioning the plurality of on-vehicle reduced order linear data-driven battery models to correspond to the plurality of remote reduced order linear data-driven battery models that are partitioned based upon the state of charge of the battery cell; and updating the plurality of on-vehicle reduced order linear data-driven battery models that have been partitioned based upon the corresponding remote model parameter for the plurality of remote reduced order linear data-driven battery models.

Another aspect of the disclosure may include executing a Kalman filter to determine the present state of charge (SOC) of the battery cell based upon the corresponding model parameters.

Another aspect of the disclosure may include periodically communicating the plurality of battery cell parameters to a remote server.

Another aspect of the disclosure may include a system for managing a battery cell that includes a controller in communication with a battery. The controller includes algorithmic code stored in a non-volatile memory device, the algorithmic code being executable to determine, for the battery cell, a plurality of battery cell parameters; develop a plurality of on-vehicle reduced order linear data-driven battery models based upon the battery cell parameters, wherein each of the plurality of on-vehicle reduced order linear data-driven battery models determines corresponding model parameters; select one of the corresponding model parameters for one of the plurality of on-vehicle reduced order linear data-driven battery models based upon a previous state of charge for the battery cell; execute a derivative-free observer to determine a present state of charge (SOC) of the battery cell based upon the corresponding model parameters; and control the battery cell based upon the SOC.

Another aspect of the disclosure may include a vehicle that includes a battery, an actuator, and a controller. The controller is operatively connected to the actuator; and the controller is in communication with the battery. The controller includes algorithmic code stored in a non-volatile memory device, the algorithmic code being executable to determine, for the battery cell, a plurality of battery cell parameters; develop a plurality of on-vehicle reduced order linear data-driven battery models based upon the battery cell parameters, wherein each of the plurality of on-vehicle reduced order linear data-driven battery models determines corresponding model parameters; select one of the corresponding model parameters for one of the plurality of on-vehicle reduced order linear data-driven battery models based upon a previous state of charge for the battery cell; execute a derivative-free observer to determine a present state of charge (SOC) of the battery cell based upon the corresponding model parameters; and control the battery cell based upon the SOC.

The above features and advantages, and other features and advantages, of the present teachings are readily apparent from the following detailed description of some of the best modes and other embodiments for carrying out the present teachings, as defined in the appended claims, when taken in connection with the accompanying drawings.

### BRIEF DESCRIPTION OF THE DRAWINGS

One or more embodiments will now be described, by way of example, with reference to the accompanying drawings, in which:

FIG. 1 schematically shows a device that includes a battery that is connected to an actuator for a device, and a controller, in accordance with the disclosure.

FIG. 2 schematically shows certain elements of a control routine for determining parameters associated with the battery described with reference to FIG. 1, in accordance with the disclosure.

FIG. 3 schematically shows other elements of the control routine for determining parameters associated with the battery described with reference to FIG. 1, in accordance with the disclosure.

The appended drawings are not necessarily to scale, and may present a somewhat simplified representation of various preferred features of the present disclosure as disclosed herein, including, for example, specific dimensions, orientations, locations, and shapes. Details associated with such features will be determined in part by the particular intended application and use environment.

### DETAILED DESCRIPTION

The components of the disclosed embodiments, as described and illustrated herein, may be arranged and designed in a variety of different configurations. Thus, the following detailed description is not intended to limit the scope of the disclosure, as claimed, but is merely representative of possible embodiments thereof. In addition, while numerous specific details are set forth in the following description in order to provide a thorough understanding of the embodiments disclosed herein, some embodiments can be practiced without some of these details. Moreover, for the purpose of clarity, certain technical material that is understood in the related art has not been described in detail in order to avoid unnecessarily obscuring the disclosure. Furthermore, the disclosure, as illustrated and described herein, may be practiced in the absence of an element that is not specifically disclosed herein. Furthermore, there is no intention to be bound by an expressed or implied theory presented in the preceding technical field, background, brief summary or the following detailed description. It should be understood that throughout the drawings, corresponding reference numerals indicate like or corresponding parts and features.

As used herein, the term “system” may refer to a combination or collection of mechanical and electrical hardware, software, firmware, electronic control component, processing logic, and/or processor device, individually or in combination, including without limitation: application specific integrated circuit (ASIC), an electronic circuit, a processor (shared, dedicated, or group) that executes one or more software or firmware programs, memory to contain software or firmware instructions, a combinational logic circuit, and/or other suitable components that provide the described functionality.

Embodiments may be described herein in terms of functional and/or logical block components and various processing steps. It should be appreciated that such block components may be realized by a number, combination or collection of mechanical and electrical hardware, software, and/or firmware components configured to perform the specified functions. For example, an embodiment may employ various combinations of mechanical components and electrical components, integrated circuit components, memory elements, digital signal processing elements, logic elements, look-up tables, or the like, which may carry out a variety of functions under the control of one or more microprocessors or other control devices. In addition, those skilled in the art will appreciate that the exemplary embodiments may be practiced in conjunction with a number of mechanical and/or electronic systems, and that the vehicle systems described herein are merely exemplary embodiment of possible implementations.

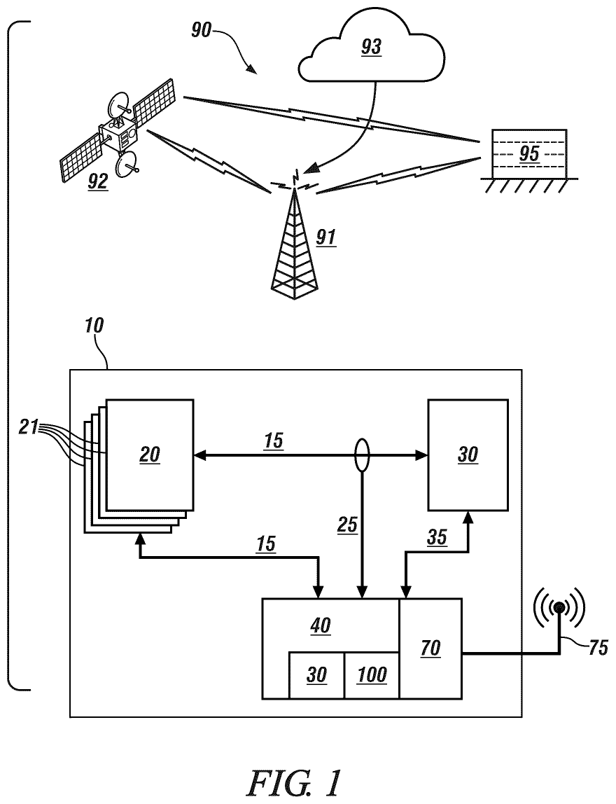

Referring to the drawings, wherein like reference numerals correspond to like or similar components throughout the several Figures, FIG. 1, consistent with embodiments disclosed herein, illustrates a device 10 that includes a rechargeable battery 20 that may provide electrical power 15 to an actuator 30, wherein operation is controlled by a controller 40. The battery 20 is composed of a plurality of battery cells 21. In one embodiment, the plurality of battery cells 21 are lithium-polymer devices or another rechargeable electrochemical configuration that is arranged to supply electric power. The device 10 may be a vehicle, a cellular telephone, etc. When the device 10 is in the form of a vehicle, the vehicle may include, but not be limited to a mobile platform in the form of a commercial vehicle, industrial vehicle, agricultural vehicle, passenger vehicle, aircraft, watercraft, train, all-terrain vehicle, personal movement apparatus, robot and the like to accomplish the purposes of this disclosure. The actuator 30 may be a simple electric machine, a power inverter and multi-phase electric machine coupled to a drive wheel of a vehicle, a telecommunications device, an LED screen, etc., without limitation.

Sensors are arranged to monitor battery parameters 25 that are associated with the battery 20, including, e.g., a current sensor, a voltmeter, a temperature sensor, etc. Other sensors and on-board models may be arranged in combination with the foregoing sensors to monitor the battery parameters 25, which may include voltage (V), current (I), and temperature (T). The controller 40 is arranged to monitor the sensors and execute the on-board models to determine the battery parameters 25. The controller 40 is also arranged to monitor actuator parameters 35, such as torque, power consumption, etc., for purposes of control, diagnostics, etc.

The controller 40 is in communication with an on-board telematics system 70 and antenna 75. The telematics system 70 includes a wireless telematics communication system capable of extra-vehicle communication, including communicating with a communication network 90 having wireless and wired communication capabilities. The extra-vehicle communications may include short-range vehicle-to-vehicle (V2V) communication and/or vehicle-to-everything (V2x) communication, which may include communication with an infrastructure monitor, e.g., a traffic camera. Alternatively, or in addition, the telematics system 70 may include wireless telematics communication systems that are capable of short-range wireless communication to a handheld device, e.g., a cell phone, a satellite phone or another telephonic device. In one embodiment the handheld device includes a software application that includes a wireless protocol to communicate with the telematics system 70, and the handheld device executes the extra-vehicle communication, including communicating with an off-board server via the wireless communication network. Alternatively, or in addition, the telematics system 70 may execute the extra-vehicle communication directly by communicating with the remote facility 95 via the communication network 90.

The communication network 90 may include cellular communication 91 and/or satellite communication 92 to effect communication with a cloud-based system 93 and/or a remote facility 95. As employed herein, the terms “cloud”, “cloud-based”, and related terms may be defined as a model for enabling ubiquitous, convenient, on-demand network access to a shared pool of configurable computing resources (e.g., networks, servers, storage, applications, and services) that can be rapidly provisioned via virtualization and released with minimal management effort or service provider interaction, and then scaled accordingly. A cloud model can be composed of various characteristics (e.g., on-demand self-service, broad network access, resource pooling, rapid elasticity, measured service, etc.), service models (e.g., Software as a Service (“SaaS”), Platform as a Service (“PaaS”), Infrastructure as a Service (“IaaS”), and deployment models (e.g., private cloud, community cloud, public cloud, hybrid cloud, etc.).

The term “controller” and related terms such as microcontroller, control module, module, control, control unit, processor and similar terms refer to one or various combinations of Application Specific Integrated Circuit(s) (ASIC), Field-Programmable Gate Array (FPGA), electronic circuit(s), central processing unit(s), e.g., microprocessor(s) and associated non-transitory memory component(s) in the form of memory and storage devices (read only, programmable read only, random access, hard drive, etc.). The non-transitory memory component is capable of storing machine readable instructions in the form of one or more software or firmware programs or routines, combinational logic circuit(s), input/output circuit(s) and devices, signal conditioning and buffer circuitry and other components that can be accessed by one or more processors to provide a described functionality. Input/output circuit(s) and devices include analog/digital converters and related devices that monitor inputs from sensors, with such inputs monitored at a preset sampling frequency or in response to a triggering event. Software, firmware, programs, instructions, control routines, code, algorithms and similar terms mean controller-executable instruction sets including calibrations and look-up tables. Each controller executes control routine(s) to provide desired functions. Routines may be executed at regular intervals, for example each 100 microseconds during ongoing operation. Alternatively, routines may be executed in response to occurrence of a triggering event. Communication between controllers, actuators and/or sensors may be accomplished using a direct wired point-to-point link, a networked communication bus link, a wireless link or another suitable communication link. Communication includes exchanging data signals in suitable form, including, for example, electrical signals via a conductive medium, electromagnetic signals via air, optical signals via optical waveguides, and the like. The data signals may include discrete, analog or digitized analog signals representing inputs from sensors, actuator commands, and communication between controllers.

The term “signal” refers to a physically discernible indicator that conveys information, and may be a suitable waveform (e.g., electrical, optical, magnetic, mechanical or electromagnetic), such as DC, AC, sinusoidal-wave, triangular-wave, square-wave, vibration, and the like, that is capable of traveling through a medium.

The term ‘model’ refers to a processor-based or processor-executable code and associated calibration that simulates a physical existence of a device or a physical process. As used herein, the terms ‘dynamic’ and ‘dynamically’ describe steps or processes that are executed in real-time and are characterized by monitoring or otherwise determining states of parameters and regularly or periodically updating the states of the parameters during execution of a routine or between iterations of execution of the routine.

The terms “calibration”, “calibrated”, and related terms refer to a result or a process that compares an actual or standard measurement associated with a device or system with a perceived or observed measurement or a commanded position for the device or system. A calibration as described herein can be reduced to a storable parametric table, a plurality of executable equations or another suitable form that may be employed as part of a measurement or control routine.

A parameter is defined as a measurable quantity that represents a physical property of a device or other element that is discernible using one or more sensors and/or a physical model. A parameter can have a discrete value, e.g., either “1” or “0”, or can be infinitely variable in value.

The controller 40 includes one or a plurality of executable actuator control routines 100 for controlling the actuator 30 to generate torque or perform another function that utilizes electrical power.

The controller 40 includes one or a plurality of executable control routines that compose a battery control routine 100.

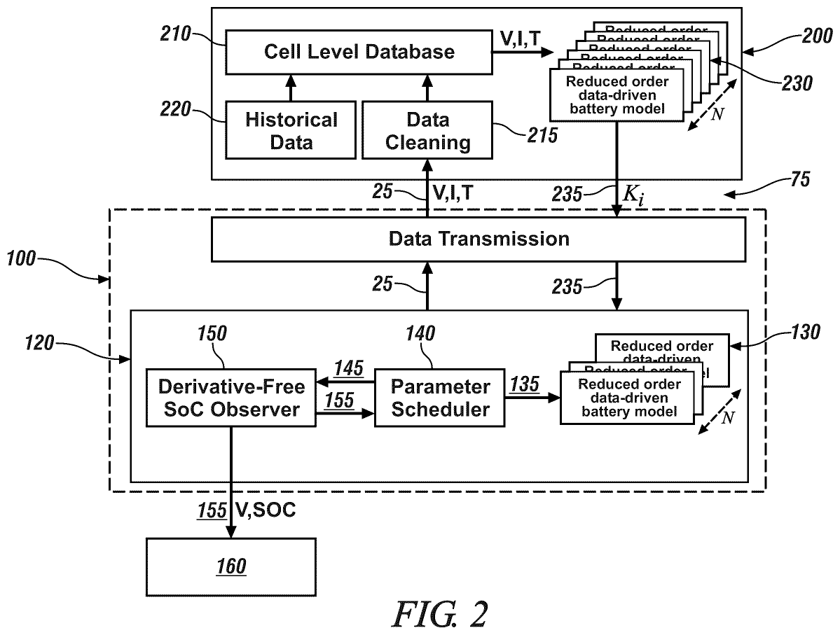

FIG. 2 schematically illustrates, with continued reference to FIG. 1, elements of the battery control routine 100 and a remote estimator routine 200. In one embodiment, the remote estimator routine 200 is cloud-based. The battery control routine 100 communicates with the remote estimator routine 200 via the telematics system 70. Battery parameters 155, e.g., battery state of charge (SOC) and voltage (V), are communicated to a second controller 160 for operation in accordance therewith.

The remote estimator routine 200 includes a historical battery database 220, a data filter (Data Cleaning) 215, a cell-level database 210, and a plurality of remote Reduced Order Linear Data-driven battery (ROLD) models 230.

The historical battery database 220 is composed of battery parameter data that has been captured and transmitted from the battery 20 during the course of its life. in one embodiment, the historical battery database 220 is composed of battery parameter data for individual battery cells 21 of the battery 20.

The data filter 215 includes a Gaussian data filter or another device that reduces random noise in the battery parameters 25, i.e., noise that occurs during observation of current, voltage, temperature, and other physical quantities, thus reducing real-time and accumulated errors in the battery parameters 25.

The cell-level database 210 is composed of the historical battery database 220 and the present battery parameters 25.

A plurality of remote reduced order linear data-driven battery (ROLD) models 230 are resident in the remote estimator routine 200.

The plurality of remote ROLD models 230 are partitioned or subdivided based upon a battery state, e.g., SOC. In one embodiment, there is a quantity of N of the remote ROLD models 230 that correlate to N SOC regions between a minimum SOC, e.g., 20%, and a maximum SOC, e.g., 100%, corresponding to the plurality of on-vehicle ROLD models 130. As such, each of the plurality of remote ROLD models 230 corresponds to and is associated with an SOC region. By way of example, a first of the remote ROLD models is associated with a first region SOC_{A} between a minimum SOC (SOC_{MIN}) and SOC₁, i.e., SOC_{MIN}<SOC_{A}<SOC₁; a second of the remote ROLD models is associated with a second region SOC_{B} between SOC₁ and SOC₂, i.e., SOC₁<SOC_{B}<SOC₂; . . . ; and an N^{th} of the remote ROLD models is associated with an N^{th} region SOC_{N} between SOC_{N-1} and a maximum SOC (SOC_{MAX}), i.e., SOC_{N-1}<SOC_{N}<SOC_{MAX}. The magnitudes of the N SOC regions may be equivalent in one embodiment, e.g., 10%, such as a first region covering an SOC range between 10% and 20%, a second region covering an SOC range between 20% and 30%, etc. Alternatively, the magnitudes of the N SOC regions may differ in one embodiment, such as a first region covering an SOC range between 10% and 30%, a second region covering an SOC range between 30% and 40%, a third region covering an SOC range between 40% and 45%, etc.

The plurality of remote ROLD models 230 employ analytical techniques to reduce the computational complexity of a full-order, high-fidelity model by learning system response characteristics from data, and preserving the expected fidelity within a satisfactory error. Working with reduced order models (ROMs) can simplify analysis and control design. Model-based ROM methods rely on a mathematical or physical understanding of the underlying model. In linear system analysis, linearization, linear parameter-varying models, and techniques such as balanced truncation and pole-zero simplification are often used to simplify the system model.

Data-driven methods use input/output data from the original high-fidelity first-principles model to construct either a dynamic or static reduced-order model that accurately represents the underlying system.

Each of the N remote ROLD models 230 generates model parameters Ki (i=1 through N) 235, which are communicated and employed by the respective on-vehicle ROLD models 130 in the determination of the battery state, e.g., SOC. The model parameters Ki (i=1 through N) 235 are communicated to the controller 40 for implementation and execution in the battery control routine 100.

The battery control routine 100 includes a routine 120 including a plurality of on-vehicle reduced order linear data-driven battery (ROLD) models 130, a parameter scheduler 140, a state of charge (SOC) observer 150, which is periodically executed to determine the battery parameters 155, e.g., battery state of charge (SOC) and voltage (V).

The battery control routine 100 regularly and/or periodically transmits data in the form of the battery parameters (VIT) 25 to the remote estimator routine 200. The remote estimator routine 200 transmits data in the form of N model parameters Ki (i=1 through N) 235 to the battery control routine 100.

The plurality of on-vehicle ROLD models 130 includes a quantity of N of the models, which are established based upon SOC region, and correspond to the plurality of remote ROLD models 230. Analogous to the remote ROLD models 230, the plurality of on-vehicle ROLD models 130 are partitioned or subdivided based upon a battery state, e.g., SOC region. In one embodiment, there is a quantity of N of the on-vehicle ROLD models 130 that correlate to N SOC regions between a minimum SOC, e.g., 20%, and a maximum SOC, e.g., 100%.

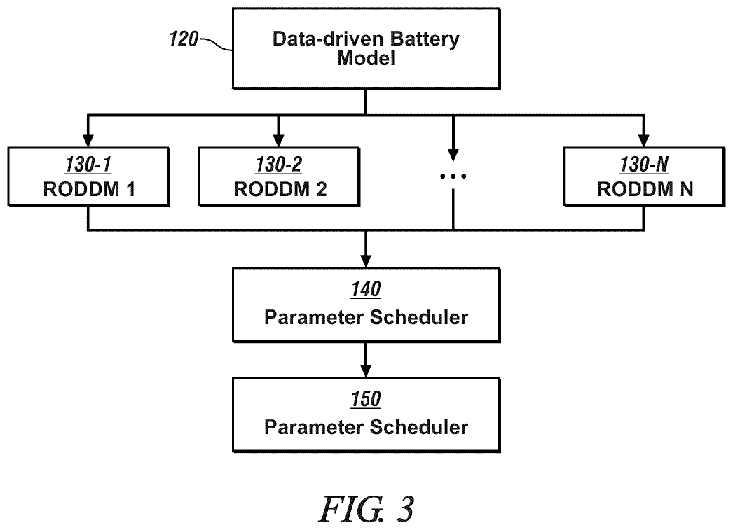

As illustrated with reference to FIG. 3, each of the plurality of on-vehicle ROLD models 130 corresponds to and is associated with an SOC region. By way of example, a first of the on-vehicle ROLD models 130-1 is associated with a first region SOC_{A} between a minimum SOC (SOC_{MIN}) and SOC₁, i.e., SOC_{MIN}<SOC_{A}<SOC₁; a second of the on-vehicle ROLD models 130-2 is associated with a second region SOC_{B} between SOC₁ and SOC₂, i.e., SOC₁<SOC_{B}<SOC₂; . . . ; and an N^{th} of the on-vehicle ROLD models 130-N is associated with an N^{th} region SOC_{N} between SOC_{N-1} and a maximum SOC (SOC_{MAX}), i.e., SOC_{N-1}<SOC_{N}<SOC_{MAX}.

The plurality of on-vehicle ROLD models 130 utilizes the same linear model structure as the remote ROLD models 230 with the same state-based partitioning, and with parameters that are adapted based on state scheduling logic. In one embodiment, and as described herein, the state-based partitioning is based upon SOC of the battery 20 or battery cell 21.

The parameter scheduler 140 selects one of the corresponding model parameters Ki 135 for one of the plurality of on-vehicle ROLD models 130 based upon a previously determined state of charge 155 for the battery cell that has been determined by the SOC observer 150 and provided as feedback, and communicates, via link 145, the selected corresponding model parameter Ki 135 to the SOC observer 150.

The SOC observer 150 determines battery parameters 155, e.g., battery state of charge (SOC) and voltage (V) based upon the respective or corresponding model parameters Ki 135. The SOC observer 150 may be a derivative-free SOC observer in one embodiment, which employs a Kalman filter (KF). In one embodiment, the Kalman filter employs a recursive algorithm to estimate SOC by combining a model of the battery dynamics with real-time measurements. In one embodiment, the Kalman filter may be an Extended Kalman Filter (EKF), which compensates for non-linearities by linearizing around the current estimate. In one embodiment, the Kalman filter may be an Unscented Kalman Filter (UKF), which compensates for non-linearities without the need for linearization.

The battery parameters 155, e.g., battery state of charge (SOC) and voltage (V), are communicated to the second controller 160 for operation in accordance therewith. When the second controller 160 is responsible for battery cell charging, the battery state of charge (SOC) and voltage (V) may be employed to control charging of the battery cell. Alternatively, when the second controller 160 interacts with controller 40 and is responsible for operation of the actuator 30, e.g., the battery state of charge (SOC) and voltage (V) may be employed to control operation of the actuator 30.

The battery control routine 100 including the plurality of on-vehicle reduced order linear data-driven battery (ROLD) models 130 and state of charge (SOC) observer 150 provide a computationally fast model for onboard estimation of the battery parameters 155.

The battery control routine 100 communicates information 25 to the remote estimator routine 200 for training of the plurality of remote ROLD models 230 in a cloud-based setting.

The arrangement of the plurality of remote ROLD models 230 and the corresponding on-vehicle ROLD models 130 enable a piecewise development of the ROLD models.

The arrangement of the SOC observer 150 employing a derivative-free approach ensures continuity in the state estimation over time and improved accuracy of the battery parameters 155.

The concepts described herein enable real-time battery state estimation, and reduce the calibration and training effort because calibration may be directly performed employing driving data instead of using pre-production lab testing, etc.

The concepts are suitable for use with a battery management system having limited computational capability and onboard memory.

The data-driven model may be trained over segmented regions of the state-space, which offers higher accuracy over the entire operating region using dedicated models.

The concepts improve reliability of model because less need for regular updates over the cloud communication.

The concepts are adaptable to different battery chemistries through the use of segmentation.

The concepts enable data sharing among fleets of vehicles of identical or vehicles having similar model/battery age/usage, which may be used to update the model using the data-driven approach.

The detailed description and the drawings or figures are supportive and descriptive of the present teachings, but the scope of the present teachings is defined solely by the claims. While some of the best modes and other embodiments for carrying out the present teachings have been described in detail, various alternative designs and embodiments exist for practicing the present teachings defined in the appended claims.

What is claimed is:

1. A method for managing a battery cell, the method comprising:
determining, for a battery cell, a plurality of battery cell parameters;
developing a plurality of on-vehicle reduced order linear data-driven battery models based upon the battery cell parameters, wherein each of the plurality of on-vehicle reduced order linear data-driven battery models determines corresponding model parameters;
selecting one of the corresponding model parameters for one of the plurality of on-vehicle reduced order linear data-driven battery models based upon a previous state of charge for the battery cell;
executing a derivative-free observer to determine a present state of charge (SOC) of the battery cell based upon the corresponding model parameters; and
controlling the battery cell based upon the SOC.

2. The method of claim 1, wherein executing the derivative-free observer to determine the present state of charge (SOC) of the battery cell based upon the corresponding second set of parameters comprises executing a Kalman filter to determine the present state of charge (SOC) of the battery cell based upon the corresponding second set of parameters.

3. The method of claim 1, further comprising:
executing the derivative-free observer to determine a voltage of the battery cell based upon the corresponding second set of parameters; and
controlling charging of the battery cell based upon the SOC and the voltage of the battery cell.

4. The method of claim 1, further comprising:
communicating the plurality of battery cell parameters to a remote server;
developing a plurality of remote reduced order linear data-driven battery models based upon the battery cell parameters, wherein each of the remote reduced order linear data-driven battery models determines a corresponding remote model parameter; and
updating the plurality of on-vehicle reduced order linear data-driven battery models based upon the corresponding remote model parameter.

5. The method of claim 4, further comprising:
partitioning the plurality of remote reduced order linear data-driven battery models based upon the state of charge of the battery cell;
determining the corresponding remote model parameter for each of the plurality of remote reduced order linear data-driven battery models that are partitioned based upon the state of charge of the battery cell;
partitioning the plurality of on-vehicle reduced order linear data-driven battery models to correspond to the plurality of remote reduced order linear data-driven battery models that are partitioned based upon the state of charge of the battery cell; and
updating the plurality of on-vehicle reduced order linear data-driven battery models that have been partitioned based upon the corresponding remote model parameter for the plurality of remote reduced order linear data-driven battery models.

6. The method of claim 1, wherein executing a derivative-free observer to determine a present state of charge (SOC) of the battery cell based upon the corresponding model parameters comprises executing a Kalman filter to determine the present state of charge (SOC) of the battery cell based upon the corresponding model parameters.

7. The method of claim 1, further comprising periodically communicating the plurality of battery cell parameters to a remote server.

8. A system for managing a battery cell, the system comprising:
a controller in communication with a battery;
the controller including algorithmic code stored in a non-volatile memory device, the algorithmic code being executable to:
determine, for the battery cell, a plurality of battery cell parameters;
develop a plurality of on-vehicle reduced order linear data-driven battery models based upon the battery cell parameters, wherein each of the plurality of on-vehicle reduced order linear data-driven battery models determines corresponding model parameters;
select one of the corresponding model parameters for one of the plurality of on-vehicle reduced order linear data-driven battery models based upon a previous state of charge for the battery cell;
execute a derivative-free observer to determine a present state of charge (SOC) of the battery cell based upon the corresponding model parameters; and
control the battery cell based upon the SOC.

9. The system of claim 8, wherein the algorithmic code being executable to the derivative-free observer to determine the present state of charge (SOC) of the battery cell based upon the corresponding second set of parameters comprises the algorithmic code being executable to execute a Kalman filter to determine the present state of charge (SOC) of the battery cell based upon the corresponding second set of parameters.

10. The system of claim 8, further comprising the algorithmic code being executable to:
execute the derivative-free observer to determine a voltage of the battery cell based upon the corresponding second set of parameters; and
control charging of the battery cell based upon the SOC and the voltage of the battery cell.

11. The system of claim 8, further comprising the algorithmic code being executable to:
communicate the plurality of battery cell parameters to a remote server;
develop a plurality of remote reduced order linear data-driven battery models based upon the battery cell parameters, wherein each of the remote reduced order linear data-driven battery models determines a corresponding remote model parameter; and
update the plurality of on-vehicle reduced order linear data-driven battery models based upon the corresponding remote model parameter.

12. The system of claim 11, further comprising the algorithmic code being executable to:
partition the plurality of remote reduced order linear data-driven battery models based upon the state of charge of the battery cell;
determine the corresponding remote model parameter for each of the plurality of remote reduced order linear data-driven battery models that are partitioned based upon the state of charge of the battery cell;
partition the plurality of on-vehicle reduced order linear data-driven battery models to correspond to the plurality of remote reduced order linear data-driven battery models that are partitioned based upon the state of charge of the battery cell; and
update the plurality of on-vehicle reduced order linear data-driven battery models that have been partitioned based upon the corresponding remote model parameter for the plurality of remote reduced order linear data-driven battery models.

13. The system of claim 8, wherein the algorithmic code being executable to execute the derivative-free observer to determine a present state of charge (SOC) of the battery cell based upon the corresponding model parameters comprises the comprising the algorithmic code being executable to execute a Kalman filter to determine the present state of charge (SOC) of the battery cell based upon the corresponding model parameters.

14. The system of claim 8, further comprising the algorithmic code being executable to periodically communicate the plurality of battery cell parameters to a remote server.

15. A vehicle, comprising:
a battery, an actuator, and a controller;
the controller operatively connected to the actuator;
the controller in communication with the battery;
the controller including algorithmic code stored in a non-volatile memory device, the algorithmic code being executable to:
determine, for the battery cell, a plurality of battery cell parameters;
develop a plurality of on-vehicle reduced order linear data-driven battery models based upon the battery cell parameters, wherein each of the plurality of on-vehicle reduced order linear data-driven battery models determines corresponding model parameters;
select one of the corresponding model parameters for one of the plurality of on-vehicle reduced order linear data-driven battery models based upon a previous state of charge for the battery cell;
execute a derivative-free observer to determine a present state of charge (SOC) of the battery cell based upon the corresponding model parameters; and
control the battery cell based upon the SOC.

16. The vehicle of claim 15, wherein the algorithmic code being executable to the derivative-free observer to determine the present state of charge (SOC) of the battery cell based upon the corresponding second set of parameters comprises the algorithmic code being executable to execute a Kalman filter to determine the present state of charge (SOC) of the battery cell based upon the corresponding second set of parameters.

17. The vehicle of claim 15, further comprising the algorithmic code being executable to:
execute the derivative-free observer to determine a voltage of the battery cell based upon the corresponding second set of parameters; and
control charging of the battery cell based upon the SOC and the voltage of the battery cell.

18. The vehicle of claim 15, further comprising the algorithmic code being executable to:
communicate the plurality of battery cell parameters to a remote server;
develop a plurality of remote reduced order linear data-driven battery models based upon the battery cell parameters, wherein each of the remote reduced order linear data-driven battery models determines a corresponding remote model parameter; and
update the plurality of on-vehicle reduced order linear data-driven battery models based upon the corresponding remote model parameter.

19. The vehicle of claim 15, wherein the algorithmic code being executable to execute the derivative-free observer to determine a present state of charge (SOC) of the battery cell based upon the corresponding model parameters comprises the comprising the algorithmic code being executable to execute a Kalman filter to determine the present state of charge (SOC) of the battery cell based upon the corresponding model parameters.

20. The vehicle of claim 15, further comprising the algorithmic code being executable to periodically communicate the plurality of battery cell parameters to a remote server.
